(19) United States
(12) Patent Application Publication
(10) Pub. No.: US 2018/0277476 A1
(43) Pub. Date: Sep. 27, 2018

(54) SEMICONDUCTOR MEMORY DEVICE AND METHOD FOR MANUFACTURING SAME

(71) Applicant: Toshiba Memory Corporation, Minato-ku (JP)

(72) Inventor: Daisuke HAGISHIMA, Meguro (JP)

(73) Assignee: Toshiba Memory Corporation, Minato-ku (JP)

(21) Appl. No.: 15/785,511

(22) Filed: Oct. 17, 2017

(30) Foreign Application Priority Data
Mar. 24, 2017 (JP) 2017-059932

(51) Int. Cl. H01L 23/528; H01L 27/1157; H01L 27/11582; H01L 23/522; H01L 23/532; H01L 21/28; H01L 21/768

(52) U.S. Cl. CPC H01L 23/528; H01L 27/1157; H01L 27/11582; H01L 23/5226; H01L 23/53271; G11C 16/14; H01L 23/53257; H01L 21/28282; H01L 21/76837; H01L 21/76883; H01L 23/53214

(57) ABSTRACT

A semiconductor memory device includes a first electrode film, a second electrode film group composed of a plurality of electrode films provided on the first electrode film, a third electrode film group composed of a plurality of electrode films provided on the first electrode film and spaced from the second electrode film group, a semiconductor member extending in a first direction in which the first electrode film and the second electrode film group are arranged, a charge storage member provided between the first electrode film and the semiconductor member, a first conductive film connecting the plurality of electrode films of the second electrode film group to each other and a second conductive film connecting the plurality of electrode films of the third electrode film group to each other.

### CROSS-REFERENCE TO RELATED APPLICATIONS

This application is based upon and claims the benefit of priority from Japanese Patent Application No. 2017-059932, filed on Mar. 24, 2017; the entire contents of which are incorporated herein by reference.

### FIELD

Embodiments relate to a semiconductor memory device and a method for manufacturing the same.

### BACKGROUND

In recent years, there has been proposed a stacked-type semiconductor memory device in which memory cells are integrated three-dimensionally. Such a stacked-type semiconductor memory device is provided with a stacked body in which electrode films and insulating films are alternately stacked on a semiconductor substrate. Semiconductor pillars are provided through the stacked body. A memory cell is formed for each crossing portion of the electrode film and the semiconductor pillar. A challenge for such a stacked-type semiconductor memory device is to improve the operating speed.

### BRIEF DESCRIPTION OF THE DRAWINGS

FIG. 1 is a perspective view showing a semiconductor memory device according to an embodiment;

FIGS. 2A and 2B are sectional views showing the semiconductor memory device according to the embodiment.

FIG. 2A shows an upper select gate line, and FIG. 2B shows a word line;

FIG. 3 is a sectional view showing the semiconductor memory device according to the embodiment;

FIGS. 4 and 5 are sectional views showing a memory cell of the semiconductor memory device according to the embodiment; and

FIGS. 6A and 6B, and 7A and 7B are sectional views showing a manufacturing method of the semiconductor memory device according to the embodiment.

### DETAILED DESCRIPTION

A semiconductor memory device according to one embodiment, includes a first electrode film, a second electrode film group composed of a plurality of electrode films provided on the first electrode film, a third electrode film group composed of a plurality of electrode films provided on the first electrode film and spaced from the second electrode film group, a semiconductor member extending in a first direction in which the first electrode film and the second electrode film group are arranged, a charge storage member provided between the first electrode film and the semiconductor member, a first conductive film connecting the plurality of electrode films of the second electrode film group to each other and a second conductive film connecting the plurality of electrode films of the third electrode film group to each other.

A method for manufacturing a semiconductor memory device, includes forming a second electrode film group and a third electrode film group by forming a groove in an upper surface of a stacked body in which insulating films and electrode films are stacked alternately along a first direction and dividing a plurality of the electrode films counting from the upper surface. The method includes forming a conductive film on a side surface of the groove. The method includes forming holes extending in the first direction in a portion of the stacked body sandwiching the groove. The method includes forming charge storage members on inner surfaces of the holes. The method includes forming semiconductor members in the holes.

An embodiment is now described below.

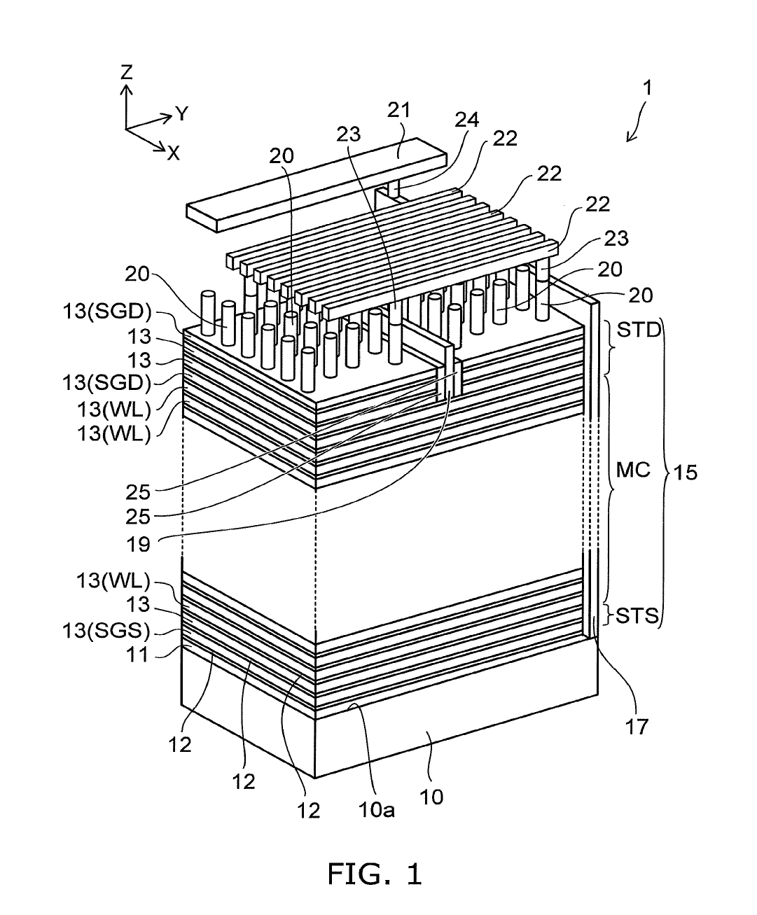

FIG. 1 is a perspective view showing a semiconductor memory device according to the embodiment.

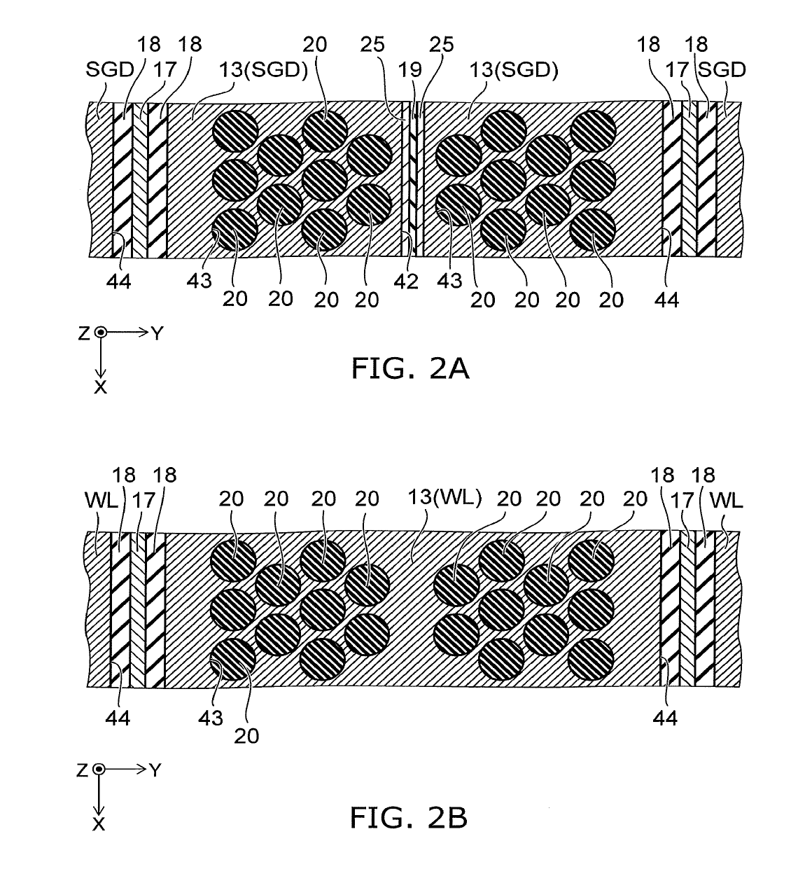

FIGS. 2A and 2B are sectional views showing the semiconductor memory device according to the embodiment. FIG. 2A shows an upper select gate line. FIG. 2B shows a word line.

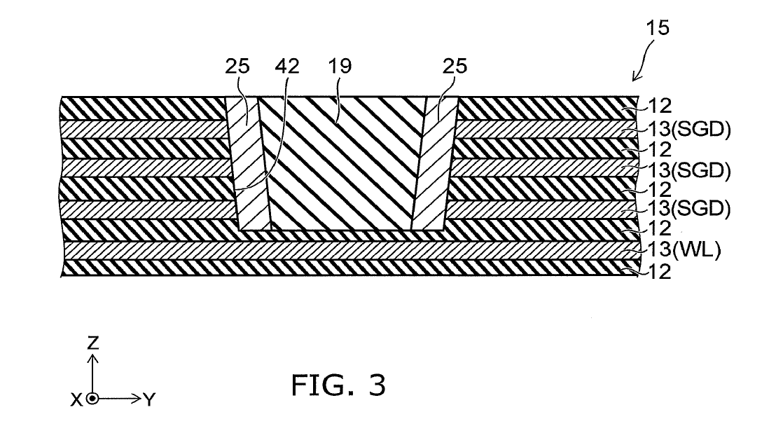

FIG. 3 is a sectional view showing the semiconductor memory device according to the embodiment.

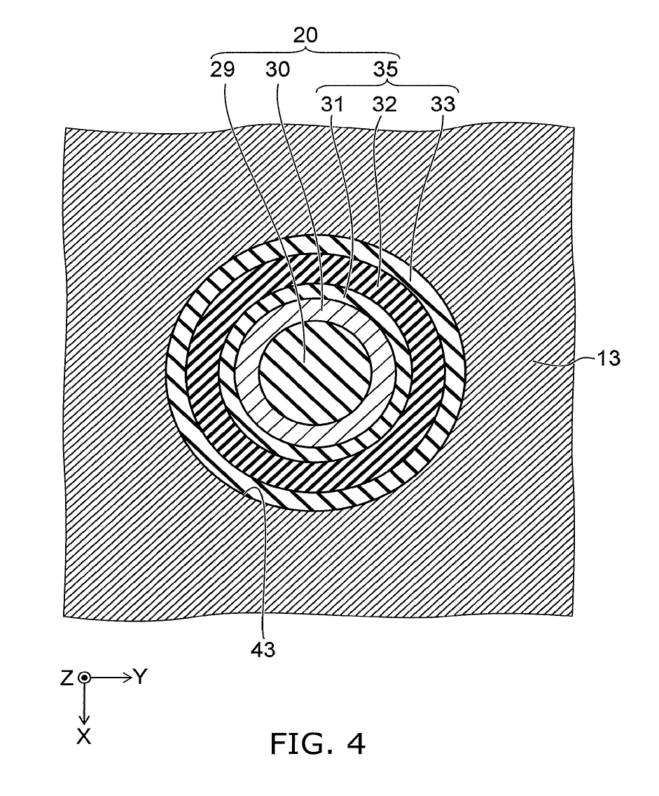

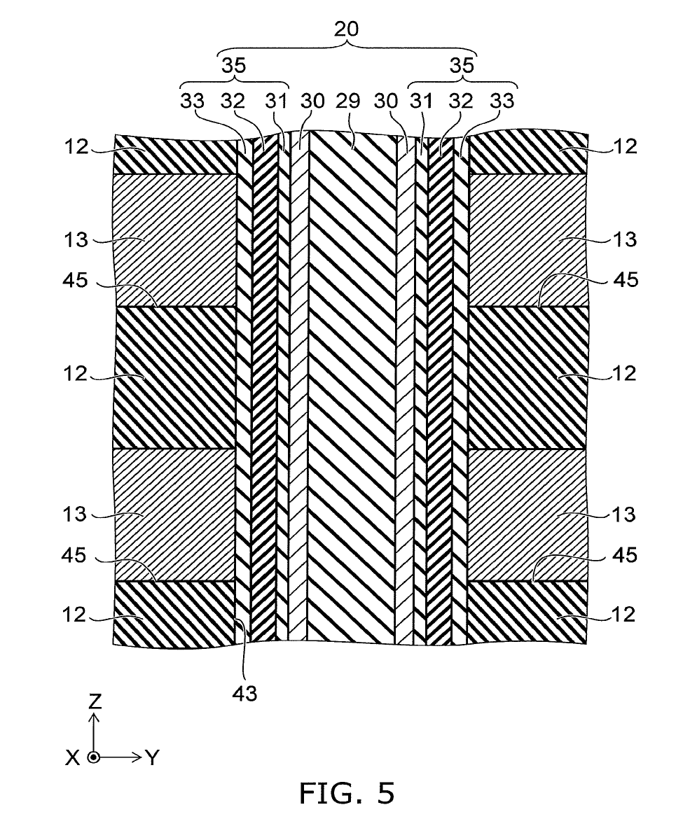

FIGS. 4 and 5 are sectional views showing a memory cell of the semiconductor memory device according to the embodiment. FIGS. 4 and 5 show cross sections orthogonal to each other.

The drawings are schematic, and are emphasized and omitted as appropriate. For instance, the depicted components are fewer and larger than in reality. The figures are not necessarily consistent in e.g. the number and size ratio of components.

The semiconductor memory device according to the embodiment is a stacked-type NAND flash memory.

As shown in FIG. 1, the semiconductor memory device 1 (hereinafter also simply referred to as “device 1”) according to the embodiment is provided with a silicon substrate 10. The silicon substrate 10 is formed from e.g. a monocrystal of silicon (Si). A silicon oxide film 11 is provided on the silicon substrate 10.

In the following, in this specification, an XYZ orthogonal coordinate system is adopted for convenience of description. Two directions parallel to the upper surface 10a of the silicon substrate 10 and orthogonal to each other are referred to as “X-direction” and “Y-direction”. The direction perpendicular to the upper surface 10a of the silicon substrate 10 is referred to as “Z-direction”. In the Z-direction, the direction from the silicon substrate 10 toward the silicon oxide film 11 is also referred to as “upper”, and the opposite direction is also referred to as “lower”. However, these expressions are also used for convenience, and irrelevant to the direction of gravity.

In this specification, the “silicon oxide film” refers to a film composed primarily of silicon oxide (SiO) and contains silicon (Si) and oxygen (O). The same also applies to the other components. That is, the component with the designation including a material name is composed primarily of that material. Furthermore, silicon oxide is generally an insulating material. Thus, unless otherwise specified, the silicon oxide film is an insulating film. The same also applies to the other components. That is, in principle, the characteristics of the member reflect the characteristics of its main ingredient. Silicon oxide films 12 and electrode films 13 are stacked alternately along the Z-direction on the silicon oxide film 11. A stacked body 15 is formed from the silicon oxide film 11, and a plurality of silicon oxide films 12 and a plurality of electrode films 13 stacked alternately. The longitudinal direction of the stacked body 15 is the X-direction. A source electrode plate 17 is provided at positions sandwiching the stacked body 15 in the Y-direction. The lower end of the source electrode plate 17 is connected to the silicon substrate 10. The electrode film 13 is shaped like a strip extending in the X-direction. The longest longitudinal direction thereof is the X-direction, the next longest width direction is the Y-direction, and the shortest thickness direction is the Z-direction.

As shown in FIGS. 1, 2A, 2B, and 3, the device 1 is provided with a plurality of stacked bodies 15 and a plurality of source electrode plates 17, arranged alternately along the Y-direction. An insulating plate 18 made of e.g. silicon oxide is provided between the stacked body 15 and the source electrode plate 17. One stacked body 15 sandwiched between two insulating plates 18 constitutes one block.

An insulating member 19 extending in the X-direction is provided in the Y-direction central part of an upper part of the stacked body 15. The insulating member 19 divides two or more, such as three, electrode films 13 counting from the uppermost layer of the stacked body 15 into two in the Y-direction. The electrode films 13 therebelow are not divided by the insulating member 19. The insulating member 19 is made of e.g. silicon oxide.

A conductive film 25 is provided on the side surface of the insulating member 19 facing the Y-direction. Two conductive films 25 placed on both Y-direction sides of the insulating member 19 are not connected to each other. On both Y-direction sides of the insulating member 19, the conductive film 25 is connected to two or more, such as three, electrode films 13 arranged along the Z-direction. In other words, two or more electrode films 13 placed on one Y-direction side as viewed from the insulating member 19 and arranged along the Z-direction are connected to each other through the conductive film 25. The conductive film 25 is formed from a conductive material such as silicon material or metal material. The silicon material is e.g. polysilicon doped with phosphorus. The metal material is e.g. aluminum (Al), tungsten (W), or tungsten silicide (WSi).

Columnar members 20 extending in the Z-direction and penetrating through the stacked body 15 are provided in the portion of the stacked body 15 sandwiching the insulating member 19. In each block, the columnar members 20 are arranged in e.g. a staggered arrangement of eight rows along the Y-direction. For instance, four rows are placed on each Y-direction side of the insulating member 19. The columnar member 20 is spaced from the insulating member 19. The columnar member 20 is not placed at a position interfering with the insulating member 19. The lower end of the columnar member 20 is in contact with the silicon substrate 10. The upper end of the columnar member 20 is exposed at the upper surface of the stacked body 15. As described later, one silicon pillar 30 (see FIGS. 4 and 5) is provided in each columnar member 20.

A source line 21 and a plurality of bit lines 22 extending in the Y-direction are provided on the stacked body 15. The source line 21 is connected to the upper end of the source electrode plate 17 through a plug 24. The bit line 22 is connected to the upper end of the silicon pillar 30 through a plug 23. Thus, a current path is formed from the bit line 22 through the plug 23, the silicon pillar 30, the silicon substrate 10, the source electrode plate 17, and the plug 24 to the source line 21. Accordingly, each silicon pillar 30 is connected between the bit line 22 and the source line 21.

As shown in FIGS. 4 and 5, in the columnar member 20, a core member 29, a silicon pillar 30, a tunnel insulating film 31, a charge storage film 32, and a block insulating film 33 are provided in this order from the central axis toward the peripheral surface. The core member 29 is made of e.g. silicon oxide. The core member 29 is shaped like a generally circular column with the axial direction in the Z-direction. The core member 29 is placed at a position including the central axis of the columnar member 20. The silicon pillar 30 is made of e.g. polysilicon. The silicon pillar 30 is shaped like a circular cylinder extending in the Z-direction and occluded at the lower end. The tunnel insulating film 31 is provided around the silicon pillar 30. The charge storage film 32 is provided around the tunnel insulating film 31. The block insulating film 33 is provided around the charge storage film 32. The tunnel insulating film 31, the charge storage film 32, and the block insulating film 33 are shaped like a circular cylinder with the axial direction in the Z-direction.

The tunnel insulating film 31 is a film that is normally insulating, but passes a tunnel current under application of a prescribed voltage within the range of the driving voltage of the device 1. For instance, the tunnel insulating film 31 is formed from silicon oxide. The charge storage film 32 is a film capable of storing charge. For instance, the charge storage film 32 is made of a material including electron trap sites, such as silicon nitride (SiN). The block insulating film 33 is a film passing substantially no current even under application of voltage within the range of the driving voltage of the device 1. For instance, the block insulating film 33 is made of silicon oxide and a high-dielectric material. A memory film 35 is formed from the tunnel insulating film 31, the charge storage film 32, and the block insulating film 33.

The electrode film 13 is formed from e.g. a conductive material such as tungsten (W). The electrode film 13 is in contact with the insulating plate 18.

In the stacked body 15, two or more electrode films 13 from the top divided by the insulating member 19 function as upper select gate lines SGD. An upper select gate transistor STD is configured for each crossing portion of the upper select gate line SGD and the columnar member 20. Two or more upper select gate lines SGD arranged along the Z-direction are connected to each other through the conductive film 25. The silicon pillars 30 penetrating through the same upper select gate line SGD are connected to mutually different bit lines 22. On each Y-direction side of the insulating member 19, an electrode film group is formed from a plurality of upper select gate lines SGD stacked along the Z-direction. That is, the insulating member 19 is placed between two electrode film groups spaced from each other in the Y-direction.

One or more electrode films 13 from the bottom function as lower select gate lines SGS. A lower select gate transistor STS is configured for each crossing portion of the lower select gate line SGS and the columnar member 20. The electrode films 13 other than the lower select gate lines SGS and the upper select gate lines SGD function as word lines WL. A memory cell MC is configured for each crossing portion of the word line WL and the columnar member 20.

Thus, a plurality of memory cells MC are connected in series along each silicon pillar 30. The lower select gate transistor STS and the upper select gate transistor STD are connected to both ends of the silicon pillar 30. Accordingly, a NAND string is formed. Dummy electrode films 13 having no electrical function may be placed between the upper select gate line SGD and the word line WL and between the lower select gate line SGS and the word line WL.

The lower select gate line SGS and the word line WL are not divided by the insulating member 19. Thus, two upper select gate lines SGD arranged at the same height are placed on one word line WL. In other words, the insulating member 19 is placed between two upper select gate lines SGD arranged at the same height.

Next, a manufacturing method of the semiconductor memory device according to the embodiment is described.

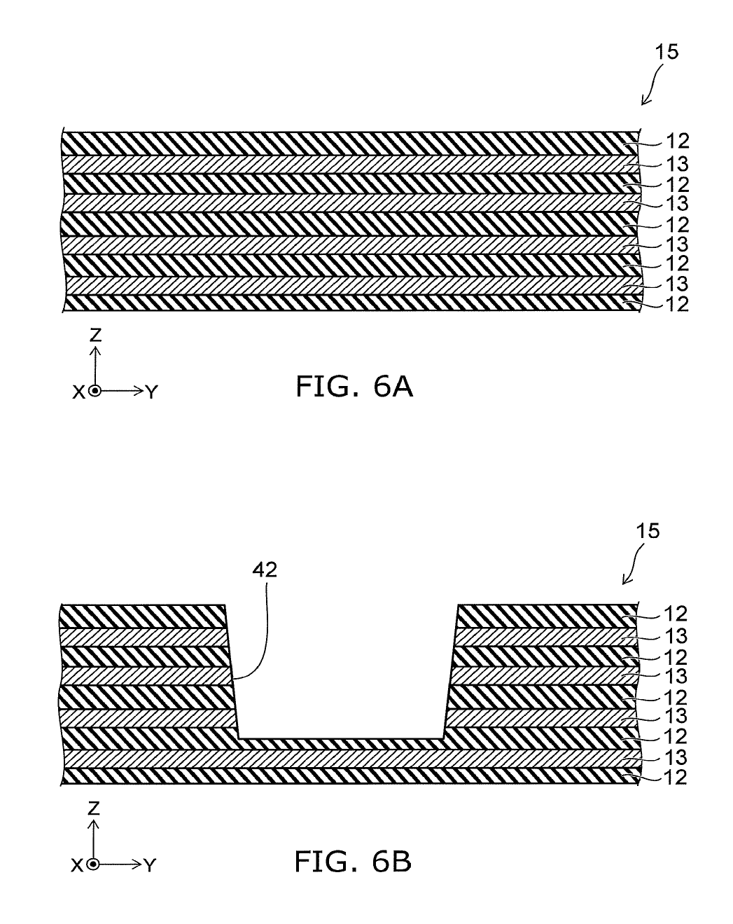

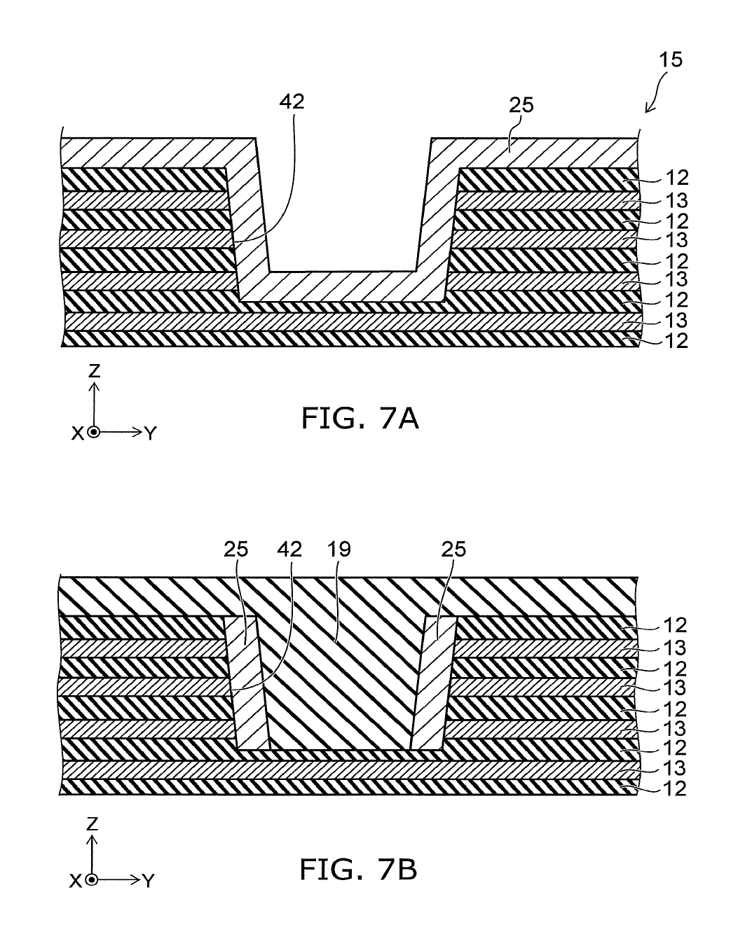

FIGS. 6A and 6B, and 7A and 7B are sectional views showing a manufacturing method of the semiconductor memory device according to the embodiment.

First, as shown in FIG. 1, a silicon oxide film 11 is formed on the silicon substrate 10.

Next, as shown in FIG. 6A, a stacked body 15 is formed on the silicon oxide film 11. The stacked body 15 includes silicon oxide films 12 and electrode films 13 stacked alternately along the Z-direction.

Next, as shown in FIG. 6B, a groove 42 extending in the X-direction is formed in an upper part of the stacked body 15. The groove 42 is caused to penetrate through two or more, such as three, electrode films 13 counting from the uppermost layer of the stacked body 15. Thus, two or more, such as three, electrode films 13 counting from the uppermost layer of the stacked body 15 are divided along the Y-direction.

Next, as shown in FIG. 7A, a conductive material is deposited on the entire surface to form a conductive film 25 on the upper surface of the stacked body 15 and on the inner surface of the groove 42. The conductive material is e.g. silicon material or metal material. The silicon material can be e.g. polysilicon doped with phosphorus (P). The metal material can be e.g. aluminum (Al), tungsten (W), or tungsten silicide (WSi).

Next, as shown in FIG. 7B, anisotropic etching such as RIE (reactive ion etching) is performed from above to etch-back the conductive film 25. As a result, the portion of the conductive film 25 deposited on the upper surface of the stacked body 15 and on the bottom surface of the groove 42 is removed, and the portion deposited on the side surface of the groove 42 is left. Next, an insulating material such as silicon oxide is deposited on the entire surface. Thus, an insulating member 19 is formed in the groove 42. At this time, of the electrode films 13, the electrode films 13 constituting upper select gate lines SGD placed on both sides of the insulating member 19 form electrode film groups on both sides of the insulating member 19, respectively. A plurality of electrode films 13 belonging to each electrode film group are connected to each other by the conductive film 25.

Next, as shown in FIGS. 4 and 5, a memory hole 43 extending in the Z-direction is formed in the stacked body 15. The memory hole 43 is caused to penetrate through the stacked body 15 to the silicon substrate 10 (see FIG. 1). Next, a block insulating film 33, a charge storage film 32, a tunnel insulating film 31, a silicon pillar 30, and a core member 29 are formed in this order on the inner surface of the memory hole 43. The silicon pillar 30 is connected to the silicon substrate 10.

Next, as shown in FIGS. 2A and 2B, a slit 44 extending in the X-direction is formed in the stacked body 15. The slit 44 is caused to penetrate through the stacked body 15 to the silicon substrate 10 (see FIG. 1).

Next, as shown in FIGS. 2A and 2B, e.g. silicon oxide is deposited on the inner surface of the slit 44, and then removed from the bottom surface of the slit 44. Thus, insulating plates 18 are formed on both side surfaces of the slit 44. Next, a conductive material is buried in the slit 44 to form a source electrode plate 17 between the two insulating plates 18.

Next, as shown in FIG. 1, a plug 23 is formed on the stacked body 15 and connected to the silicon pillar 30. A plug 24 is formed on the stacked body 15 and connected to the source electrode plate 17. Next, a bit line 22 is formed and connected to the plug 23. A source line 21 is formed and connected to the plug 24. Thus, the semiconductor memory device 1 according to the embodiment is manufactured.

Next, the operation of the semiconductor memory device 1 according to the embodiment is described.

In the semiconductor memory device 1, a region on one Y-direction side of one block is selected by selecting an upper select gate line SGD. One silicon pillar 30 is selected from this region on one side by selecting a bit line 22. Thus, one NAND string is selected. On the other hand, one memory cell MC is selected from this one NAND string by selecting a word line WL.

When writing data to the selected memory cell MC, the lower select gate line SGS is applied with an off-potential to turn off the lower select gate transistor STS. The upper select gate line SGD is applied with an on-potential to turn on the upper select gate transistor STD. The silicon pillar 30 is applied with a potential serving for the negative electrode, such as 0 V, through the bit line 22 and the upper select gate transistor STD. On the other hand, the word line WL is applied with a potential serving for the positive electrode. Thus, electrons are injected from the silicon pillar 30 through the tunnel insulating film 31 into the charge storage film 32. As a result, the threshold of the memory cell MC is changed, and data is written thereto.

When reading data from the selected memory cell MC, the selected word line WL is applied with a read potential such that on/off is determined depending on the threshold of the memory cell MC. The other word lines WL are applied with an on-potential such that the memory cell MC is turned on irrespective of its threshold. The lower select gate line SGS is applied with an on-potential to turn on the lower select gate transistor STS. The upper select gate line SGD is applied with an on-potential to turn on the upper select gate transistor STD. This allows a current to flow from the bit line 22 toward the source line 21. At this time, the magnitude of the flowing current depends on the threshold of the selected memory cell MC. Thus, data written in the memory cell MC can be read by detecting this current.

Furthermore, when erasing data from the selected memory cell MC, the source line 21 is applied with an erase potential, such as 20 V. Thus, hole-electron pairs are generated in the silicon pillar 30. Among them, holes are stored in the silicon pillar 30. Then, by applying the selected word line WL with 0 V, the holes stored in the silicon pillar 30 are injected into the charge storage film 32 through the tunnel insulating film 31. As a result, data is erased from the memory cell MC.

Next, the effect of the embodiment is described.

In the embodiment, a conductive film 25 is provided on the side surface of the insulating member 19 and connected to a plurality of upper select gate lines SGD. Thus, the conductive film 25 serves as an additional current path. This can reduce the electrical resistance of the interconnect structural body composed of the plurality of upper select gate lines SGD and the conductive film 25. Furthermore, a plurality of upper select gate lines SGD are connected to each other by the conductive film 25. Thus, the plurality of upper select gate lines SGD can be reliably applied with the same potential at the same timing. This can reduce malfunctions due to interconnect delay and improve the operating speed of the semiconductor memory device 1.

The embodiment described above can realize a semiconductor memory device having high operating speed and a method for manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first electrode film;
a second electrode film group composed of a plurality of electrode films provided on the first electrode film;
a third electrode film group composed of a plurality of electrode films provided on the first electrode film and spaced from the second electrode film group;
a semiconductor member extending in a first direction in which the first electrode film and the second electrode film group are arranged;
a charge storage member provided between the first electrode film and the semiconductor member;
a first conductive film connecting the plurality of electrode films of the second electrode film group to each other; and
a second conductive film connecting the plurality of electrode films of the third electrode film group to each other.

2. The device according to claim 1, further comprising:
an insulating member provided between the first conductive film and the second conductive film.

3. The device according to claim 1, wherein the first conductive film and the second conductive film contain one or more materials selected from the group consisting of silicon, aluminum, tungsten, and tungsten silicide.

4. A method for manufacturing a semiconductor memory device, comprising:
forming a second electrode film group and a third electrode film group by forming a groove in an upper surface of a stacked body in which insulating films and electrode films are stacked alternately along a first direction and dividing a plurality of the electrode films counting from the upper surface;
forming a conductive film on a side surface of the groove,
forming holes extending in the first direction in a portion of the stacked body sandwiching the groove;
forming charge storage members on inner surfaces of the holes; and
forming semiconductor members in the holes.

5. The method according to claim 4, wherein
the forming a conductive film includes:
depositing a conductive material on the upper surface of the stacked body and on an inner surface of the groove; and
removing a portion of the conductive material deposited on the upper surface of the stacked body and on a bottom surface of the groove.

6. The method according to claim 4, further comprising:
forming an insulating member in the groove after the forming a conductive film.
